(19) United States
(12) Patent Application Publication
(10) Pub. No.: US 2007/0217470 A1
(43) Pub. Date: Sep. 20, 2007

(54) Laser diode stack end-pumped solid state laser

(75) Inventors: Mark Joseph DeFranza, Ridgefield, WA (US); David Clifford Dawson, Brush Prairie, WA (US); Jason Nathaniel Farmer, Vancouver, WA (US)

Correspondence Address: PATENT LAW OFFICE OF DAVID G. BECK, P. O. BOX 1146, MILL VALLEY, CA, 94942, US

(73) Assignee: nLight Photonics Corporation, Vancouver, WA (US)

(21) Appl. No.: 11/436,232

(22) Filed: May 18, 2006

Related U.S. Application Data
(63) Continuation-in-part of application No. 11/384,940, filed on Mar. 20, 2006.

(51) Int. Cl. H01S 3/04; H01S 5/00

(52) U.S. Cl. 372/50.12; 372/36

(57) ABSTRACT

An end-pumped solid state laser utilizing a laser diode stack of laser diode subassemblies as the pump source is provided. The laser gain medium of the solid state laser is contained within a laser cavity defined by a pair of reflective elements. Each laser diode subassembly includes a submount to which one or more laser diodes are attached. The fast axis corresponding to each output beam of each laser diode is substantially perpendicular to the mounting surfaces of the submount. The laser diodes can be of one wavelength or multiple wavelengths. Preferably the submount has a high thermal conductivity and a CTE that is matched to that of the laser diode. On top of the submount, adjacent to the laser diode, is a spacer. The laser diode stack is formed by mechanically coupling the bottom surface of each submount to the spacer of an adjacent submount assembly. Preferably the laser diode stack is thermally coupled to a cooling block.

### CROSS-REFERENCE TO RELATED APPLICATION

This application is a continuation-in-part of U.S. patent application Ser. No. 11/384,940, filed Mar. 20, 2006, the disclosure of which is incorporated herein by reference for any and all purposes.

### FIELD OF THE INVENTION

The present invention relates generally to semiconductor lasers and, more particularly, to an end-pumped solid state laser utilizing a laser diode stack as the pump source.

### BACKGROUND OF THE INVENTION

High power laser diodes, due to their size, efficiency and wavelength range, are well suited for pumping high power solid state lasers. In such laser systems the output from one or more laser diodes is coupled into a laser gain medium, the gain medium contained within a laser cavity defined by a pair of mirrors or reflective coatings disposed at either end of the medium. The laser diode output may be coupled into either an end surface of the gain medium, creating an end-pumped laser, or into one or more side surfaces of the gain medium, creating a side-pumped laser. End-pumped lasers are typically of lower power than side-pumped lasers due to the difficulty in coupling the output from multiple laser diodes into the relatively small end surface of the gain medium.

U.S. Pat. No. 4,653,056 discloses a neodymium YAG (Nd:YAG) laser that is end-pumped by a gallium aluminum arsenide (GaAlAs) diode array. A first lens collimates the diverging beam emitted by the diode array while a second lens focuses the beam into the back end of the Nd:YAG crystal. The pumping volume was matched to that of the lasing volume in order to optimize pumping efficiency.

An alternate pumping configuration is disclosed in U.S. Pat. No. 4,665,529. In the disclosed system, the output of the pump laser diode is coupled to the laser head using a removable optical fiber with a focusing sphere imaging the pump radiation into the rod-shaped laser gain medium. The pumping volume of the laser diode is matched to the lasing volume of the gain medium. A goal of the disclosed system is to provide a versatile system in which multiple laser heads can be interchanged with a single pump source. Additionally by separating the pump source from the laser head via an optical fiber, the size of the laser head could be optimized for a variety of applications.

In order to overcome the limitations imposed by the relatively small size of the end surface of a laser gain medium and yet still end-pump the medium, U.S. Pat. No. 4,837,771 discloses using a laser cavity with a tightly folded zig-zag configuration within a block of the gain medium. By folding the cavity, the longitudinal axis of the resonator is substantially normal to the side surface of the gain medium. As a result, a laser bar in proximity to the side of the gain medium can be used to pump the cavity at a number of spaced intervals.

U.S. Pat. No. 5,170,406 discloses another configuration to efficiently couple pump energy into a laser gain medium. As disclosed, pump energy from two groups of laser diode bars is directed onto opposite end surfaces of the gain medium using an off-axis, geometric multiplexing configuration. The laser diode bars are circumferentially distributed about the optical axis in a uniform pattern and at the same distance along the optical axis from the gain medium.

Although there are a variety of end-pumped, solid state laser configurations, typically they suffer from low power, excessive complexity and excessive heat build-up. Accordingly, what is needed in the art is an end-pumped, solid state laser that overcomes these issues. The present invention provides such a system.

### SUMMARY OF THE INVENTION

The present invention provides an end-pumped solid state laser utilizing a laser diode stack of laser diode subassemblies as the pump source. The laser gain medium of the solid state laser is contained within a laser cavity defined by a pair of reflective elements. Each laser diode subassembly includes a submount to which one or more laser diodes are attached. The fast axis of each laser diode's output beam is substantially perpendicular to the submount mounting surfaces. Exemplary laser diodes include single mode single emitter laser diodes, broad area multi-mode single emitter laser diodes, and multiple single emitters fabricated on either a single substrate or on multiple substrates. The laser diodes can be of one wavelength or multiple wavelengths. Preferably the submount has a high thermal conductivity and a CTE that is matched to that of the laser diode. In an exemplary embodiment the submount is fabricated from 90/10 tungsten copper and the laser diode is attached to the submount with a gold-tin solder. An electrically isolating pad is attached to the same surface of the submount as the laser diode. A metallization layer is deposited onto the outermost surface of the electrically isolating pad, to which an electrical contact pad is bonded. Electrical interconnects, such as wire or ribbon interconnects, connect the single emitter laser diode to the metallization layer. Preferably the laser diode stack is formed by electrically and mechanically bonding together the bottom surface of each submount to the electrical contact pad of an adjacent subassembly, for example using a silver-tin solder.

To provide package cooling, the laser diode stack is thermally coupled to a cooling block, the cooling block preferably including a slotted region into which the laser diode stack fits. In at least one preferred embodiment of the invention, thermally conductive and electrically isolating members are first bonded to the bottom and side surfaces of each submount and then bonded to the cooling block, the members being interposed between the laser diode stack and the cooling block. Preferably the cooling block is comprised of a pair of members, thus insuring good thermal coupling between the laser diode stack and the cooling block.

In at least one embodiment of the invention, coupling optics are interposed between the end surface of the laser gain medium and the laser diode stack.

A further understanding of the nature and advantages of the present invention may be realized by reference to the remaining portions of the specification and the drawings.

### BRIEF DESCRIPTION OF THE DRAWINGS

FIG. 1 is an illustration of an end-pumped solid state laser in accordance with the invention;

FIG. 2 is an illustration of the end view of a typical laser bar according to the prior art;

FIG. 3 is an illustration of a stack of arrays arranged to efficiently couple into an optical fiber;

FIG. 4 is an illustration of an alternate array stacking arrangement;

FIG. 5 is an illustration of an alternate array stacking arrangement utilizing arrays of two different sizes;

FIG. 6 is an illustration of an alternate array stacking arrangement utilizing arrays of three different sizes;

FIG. 7 is an illustration of a non-rectilinear array stacking arrangement;

FIG. 8 is an end view of the output from a laser diode stack in accordance with the invention;

FIG. 9 is an end view of the output from an alternate laser diode stack, the stack including subassemblies with varying numbers of emitters;

FIG. 10 is a cross-sectional view of the laser diode stack shown in FIG. 9, with the inclusion of a coupling optic for each subassembly;

FIG. 11 is a perspective view of laser diode subassembly in accordance with the invention;

FIG. 12 is a perspective view of a laser diode stack comprised of multiple subassemblies;

FIG. 13 is a perspective view of the laser diode stack of FIG. 11 along with an electrically isolating backplane member;

FIG. 14 is a perspective view of the laser diode stack of FIG. 12 along with electrically isolating side frame members and a pair of contact assemblies; and

FIG. 15 is a perspective view of the laser diode stack of FIG. 13 attached to a cooling block.

### DESCRIPTION OF THE SPECIFIC EMBODIMENTS

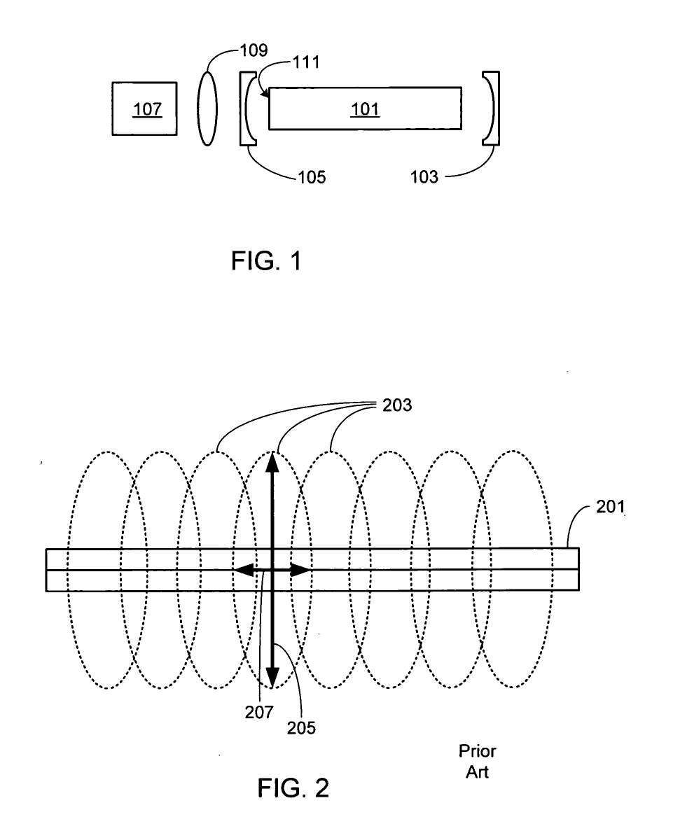

FIG. 1 is an illustration of a laser system in accordance with the invention. As shown, the laser cavity includes a laser gain medium 101, an output coupler 103 comprised of a partial reflector, and a rear reflector 105. Although in the illustrated example laser gain medium is cylindrically-shaped (i.e., a rod), it will be appreciated that the laser gain medium can be any appropriately doped glass or crystal of any shape, and that cylindrically-shaped and rectangularly-shaped (i.e., slab shaped) medium are but two exemplary shapes. It will also be appreciated that either one or both reflectors 103 and 105 can be separate from gain medium 101 as shown, or deposited directly onto the end surface or surfaces of the gain medium as is known by those of skill in the art. External to the laser cavity is at least one laser diode assembly 107 comprised of at least two laser diode subassemblies. As described in detail below, the laser diode subassemblies of assembly 107 do not utilize laser diode bars. Preferably the system also includes at least one coupling optic 109, optic 109 focusing the output of laser diode stack 107 into gain medium 101 through an end surface 111.

As the mode volume of a gain medium, for example a cylindrical gain medium, is quite limited, the power of a laser diode or a laser diode array that can be coupled into the end surface of the gain medium is determined not by the output power of the laser diode/array, but rather by the overlap of the mode of the laser diode/array and the mode volume of the gain medium. Accordingly, since the critical parameter is the gain/mode overlap efficiency, the important characteristics of a pump source are not only its power, but also the brightness and the symmetry of the output beam.

FIG. 2 shows the end view of a typical laser bar 201 according to the prior art. As shown, the divergence of the output of each emitter is non-uniform, each emitter emitting an elliptical beam 203 with the divergence in axis 205 (i.e., the fast axis) perpendicular to the diode junction being approximately 4 to 5 times the divergence along axis 207 (i.e., the slow axis). Typically the divergence in the fast axis is in the range of 20° to 40° while the divergence in the slow axis is in the range of 4° to 10°. Note that for illustration clarity, only 8 beams 203 are shown in FIG. 2 although it will be appreciated that a typical laser bar includes many more emitters.

A laser bar, which is approximately 1 centimeter in width, typically includes between 10 and 80 emitters, the emitters laterally spread across the width of the bar. Although the lateral aperture of the individual emitters is typically on the order of 50 to 300 microns, the lateral aperture of the bar is on the order of 0.8 to 0.9 centimeters. The vertical aperture of a laser bar, i.e., measured in the fast axis, is on the order of 1 to 2 microns.

Due to the large lateral aperture and the slow axis divergence of a laser bar, as noted above, the brightness of a high power laser bar is relatively low. For example, assuming an output power of 100 watts, a lateral aperture of 0.8 centimeters, a vertical aperture of 1 micron, a slow axis beam divergence of 10° (174.53 milliradians) and a fast axis divergence of 50° (872.66 milliradians), the brightness of such a laser bar is only 0.08 watts/(mm-mrad)². In comparison, approximately the same brightness can be achieved with a much smaller, lower power array. For example, assuming an array of 2 emitters with a total output power of 12 watts, a lateral aperture of 0.1 centimeters (100 micron emitters on 1 millimeter centers), a vertical aperture of 1 micron, a slow axis beam divergence of 10° (174.53 milliradians) and a fast axis divergence of 50° (872.66 milliradians), the brightness is 0.08 watts/(mm-mrad)².

Although in the above example the laser bar and the 2 emitter array exhibit approximately equivalent brightness, the laser bar suffers from a variety of drawbacks that make it less desirable for end-pumping a gain medium. One issue with the laser bar is its mode volume in comparison to that of a gain medium. While the mode volume of the laser bar in the above example is 1218 (millimeters-milliradian)², the mode volume of the above-described 2 emitter array, which exhibits comparable brightness to the laser bar, was only 152 (millimeters-milliradian)². Therefore eight of the 2 emitter arrays have approximately the same mode volume as the laser bar. As such, it is possible to couple much more pump power into the laser rod with smaller arrays than with a laser rod.

In addition to increasing the amount of power that can be pumped into the laser rod, a smaller array such as the one noted above also has significant heat dissipation advantages over a laser bar. In a laser bar the center-to-center spacing of the emitters is relatively small, thus providing the desired packing density of emitters within the bar. As a result, heat generated by the individual emitters does not have any space available for lateral heat spreading, thereby requiring all of the generated heat to be vertically dissipated through the bottom surface of the device. Therefore a laser bar with an 80 percent fill factor, 100 micron wide emitters, center-to-center spacing of 125 microns, and a 6 watt per emitter heat load has a calculated maximum emitter temperature of 105° C. Accordingly the laser bar must be operated at a lower power per emitter in order to achieve an acceptable temperature level. In contrast, the individual emitters in the above exemplary array with only two 6 watt emitters separated by a millimeter can dissipate the generated heat both vertically and laterally, with the two emitters exhibiting minimal thermal cross talk and operating at a maximum temperature of approximately half that of the emitters in the laser bar. Due to the lower operating temperature, not only can the emitters in the array operate at full power, they are also less likely to suffer from heat induced damage. Additionally the heat dissipation requirements placed on the laser diode system are less demanding, thus allowing a smaller, more robust system to be utilized.

Another issue that affects the performance of laser bars more than small arrays is smile, a term that refers to the warping of a laser diode during processing. In general, the larger the device, the greater the degree of smile experienced during processing. Accordingly, a laser bar will typically experience a greater degree of smile than a small multi-emitter array such as the exemplary array discussed above. Since smile causes the individual emitters to be at different heights, the primary effect is to increase the effective vertical aperture of the laser bar, thereby decreasing the brightness of the bar. For example, assuming a modest smile in the exemplary laser bar described above, the effective vertical aperture changes from 1 micron to 2 microns. This, in turn, causes a decrease in the brightness by 50 percent (i.e., to 0.04 watts/(mm-mrad)²) and a doubling of the mode volume (i.e., to 2,436 (millimeters-milliradian)²). Thus in this instance not only has the smile decreased the brightness of the laser bar to half that of the 2 emitter array, it has also doubled the bar's mode volume, giving the exemplary 2 emitter array a factor of 16 better performance in terms of mode volume. Note that small arrays such as the previously described 2 emitter array, due to its very small size, will typically experience an inconsequential degree of smile.

In light of the noted deficiencies of laser bars, the present invention utilizes a laser diode pump assembly consisting of at least two, and preferably more than two, array subassemblies where each array subassembly includes a submount and at least one single emitter, and preferably at least two single emitters. The array subassemblies cannot use diode laser bars. The single emitters of each array can be either single mode single emitter laser diodes or broad area multi-mode single emitter laser diodes. Furthermore the multiple emitters of each individual array can either be fabricated on a single substrate or on individual substrates.

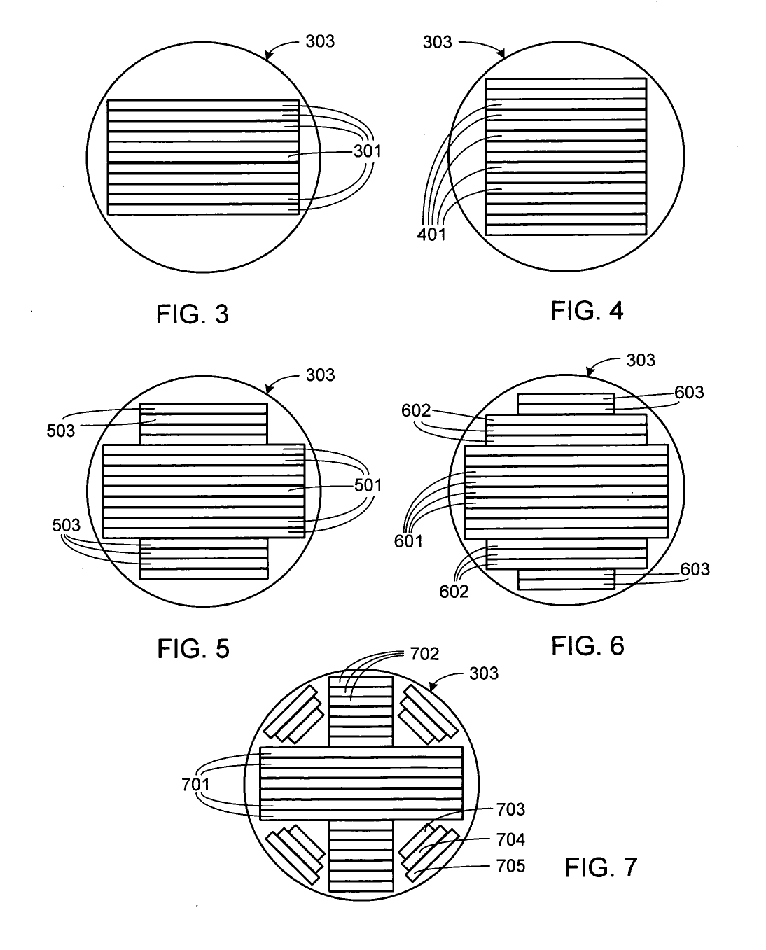

Depending upon the mode volume of the laser gain medium as well as the power requirements of the system, a variety of laser diode pump configurations can be used. For example, and as illustrated in FIGS. 3 and 4, a simple stack of equivalently sized arrays (i.e., 301 in FIGS. 3 and 401 in FIG. 4) can be used such that the mode volume of each individual array as well as the combined outputs efficiently couples into the laser gain medium 303. Furthermore, due to the flexibility of the present approach, arrays of varying sizes can be used to maximize the input into the laser rod. For example, FIG. 5 illustrates the use of a stack of arrays consisting of two array sizes 501 and 503, where arrays 501 include more emitters (for example, 4 emitters) than arrays 503 (for example, 3 emitters). Similarly, FIG. 6 illustrates the use of a stack of arrays consisting of three array sizes 601-603 where, for example, array 601 includes 4 emitters per array, array 602 includes 3 emitters per array, and array 603 includes 2 emitters per array. Alternately, utilizing simple optical systems, non-rectilinear arrays can be used as shown in FIG. 7, for example using arrays 701-705.

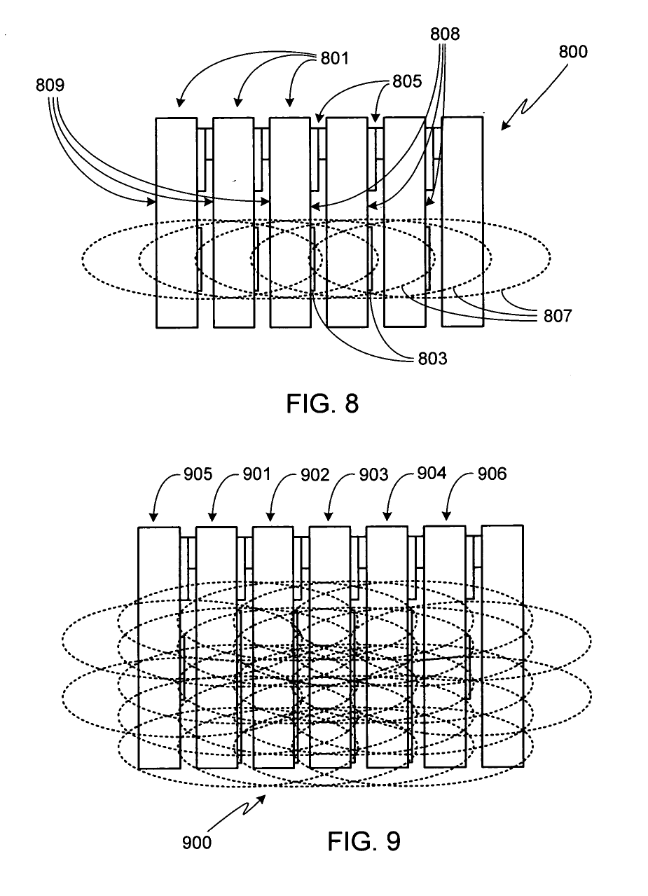

FIG. 8 is an end view of the output from a laser diode stack 800 in accordance with the invention. Although the laser diode pump assembly of the invention can utilize any number of laser diode array subassemblies positioned in a variety of configurations as previously noted and utilizing varying numbers of emitters per subassembly, in this figure laser diode pump assembly 800 includes five laser diode array subassemblies 801, each of which includes a single diode laser emitter 803 and one or more spacers 805. In marked contrast to the output beam from a laser bar, the fast axis of the output beams 807 from the laser diode array subassemblies are co-aligned (e.g., the fast axis of each output beam 807 is substantially perpendicular to the submount mounting surfaces 808 and 809). Additionally the laser diode pump assembly in accordance with the invention can be designed to efficiently overlap the mode volume of the gain medium as previously noted, both through the selection of an appropriate number of array subassemblies and by the number of laser diode emitters located on each subassembly. For example, laser diode pump assembly 900 shown in FIG. 9 includes 6 subassemblies in which the middle four subassemblies 901-904 each include 5 emitters while the two end subassemblies 905-906 each include 2 emitters.

In addition to providing a pump laser that can be sized to efficiently couple into the gain medium, the present invention also provides a means of compensating for temperature induced variations in the pump wavelength. As is well known by those of skill in the art, since the output wavelength of a laser diode varies with temperature, the pumping efficiency may vary as the system changes temperature and the pump wavelength varies from the optimal wavelength. As a result of this variation, the output of a conventional solid state laser may also vary with temperature. The laser diode stack of the present invention, however, can be designed to operate at multiple wavelengths simply by including emitters of different wavelengths. Thus, for example, one group of emitters can be the primary pump source at the initial temperature, then a second group of emitters can become the primary pump source as the system temperature increases with time, then a third group of emitters can become the primary pump source as the temperature increases further, etc. These wavelength-grouped emitters are preferably spread throughout the entire laser diode stack, thus insuring that the entire volume of the gain medium is efficiently pumped. In a preferred configuration, each subassembly includes multiple laser diode emitters, preferably on individual substrates, each operating at a different wavelength. It will be appreciated that there are a variety of possible configurations depending upon the number of desired wavelengths, the number of subassemblies, and the number of emitters per subassembly.

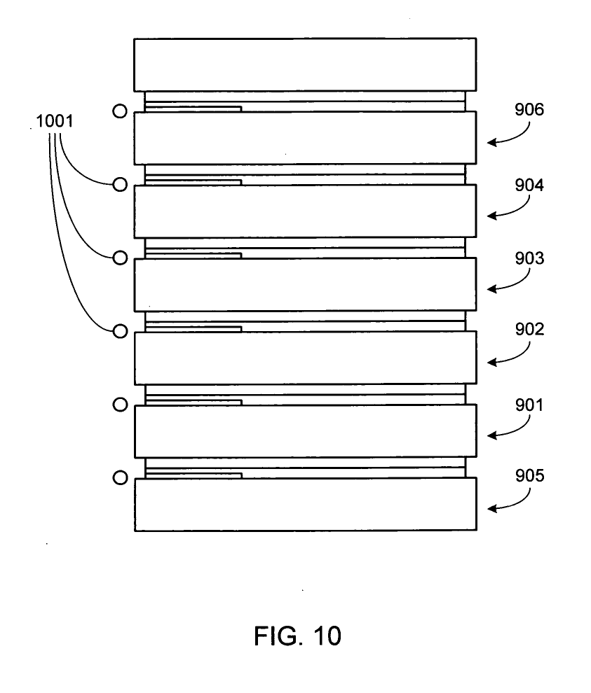

Regardless of the laser diode pump configuration, and as previously noted, in a typical configuration there is at least one coupling optic interposed between the output of each laser emitter and the laser resonator cavity/gain medium. For example, assuming an array such as the one shown in FIG. 9, preferably a lens 1001 would be located adjacent to the output of each laser diode array subassembly in order to reduce the divergence in the fast axis, as shown in the cross-sectional view of FIG. 10. Lens 1001 can be a simple cylindrical lens or a multi-element lens, for example as disclosed in co-pending U.S. patent application Ser. No. 11/252,778, the disclosure of which is incorporated herein for any and all purposes. It will be appreciated that the present invention is not limited to a specific lens or lens arrangement and that the above description is simply intended as an exemplary configuration.

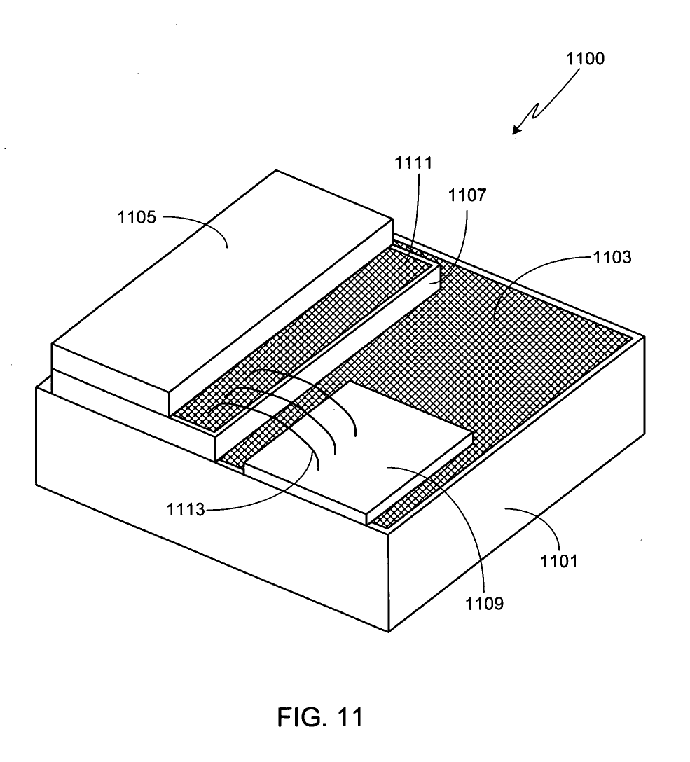

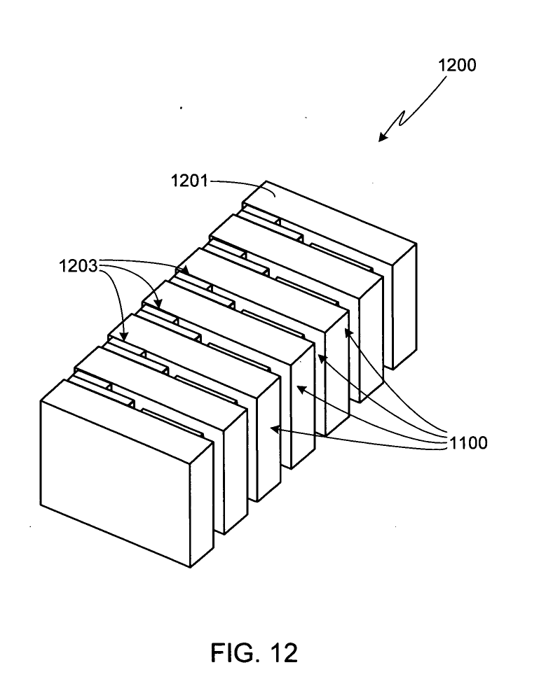

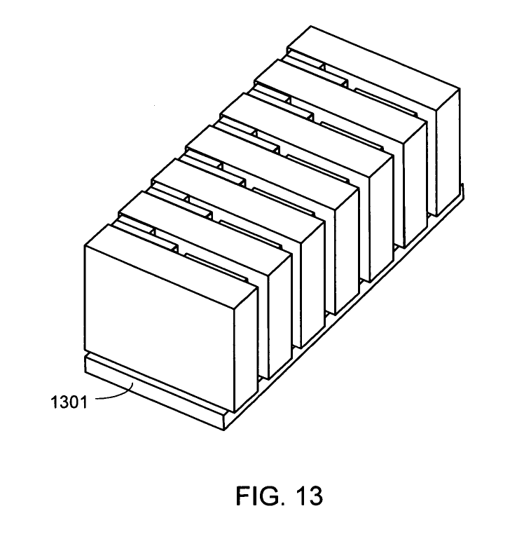

FIG. 11 is an illustration of a laser diode array subassembly 1100. To achieve the desired levels of performance and reliability, preferably submount 1101 is comprised of a material with a high thermal conductivity and a CTE that is matched to that of the laser diode. Exemplary materials include copper tungsten, copper molybdenum, and a variety of matrix metal and carbon composites. In a preferred embodiment, a 90/10 tungsten copper alloy is used. On the upper surface of submount 1101 is a layer 1103 of a bonding solder. Solder layer 1103 is preferably comprised of gold-tin, thus overcoming the reliability issues associated with the use of indium solder as a means of bonding the laser diode to the substrate.

On top of submount 1101 is a spacer that is preferably comprised of a first contact pad 1105, preferably used as the N contact for the laser diode, and an electrically insulating isolator 1107 interposed between contact pad 1105 and submount 1101. Preferably insulating isolator 1107 is attached to submount 1101 via solder layer 1103. Preferably contact pad 1105 is attached to isolator 1107 using the same solder material as that of layer 1103 (e.g., Au—Sn solder). Also mounted to submount 1101 via solder layer 1103 is a laser diode 1109 positioned such that the radiation-emitting active layer of the laser is substantially parallel to the mounting surfaces of submount 1101 and the fast axis corresponding to the output beam of the radiation-emitting active layer is substantially perpendicular to the mounting surfaces of submount 1101 (e.g., surfaces 808 and 809 of FIG. 8). Exemplary laser diodes include both single mode single emitter laser diodes and broad area multi-mode single emitter laser diodes. Additionally, multiple single emitters, either fabricated on individual substrates or on a single substrate, can be mounted to submount 1101, thereby forming an array of single emitters on a single subassembly. As previously noted, the subassemblies of the invention do not utilize laser bars, both due to the size of laser bars (i.e., 1 centimeter) and their poor heat dissipation characteristics that result from close emitter packing. In this embodiment of the invention one contact of laser diode 1109, preferably the P contact, is made via submount 1101, while the second contact, preferably the N contact, is made using wire bonds, ribbon bonds, or other electrical connector which couple the laser diode to metallization layer 1111. Representative wire bonds 1113 are shown in FIG. 11.

After completion of subassembly 1100, preferably the laser diode or diodes 1109 attached to the submount are tested. Early testing, i.e., prior to assembly of the entire laser diode pump assembly, offers several advantages over testing after assembly completion. First, it allows defective laser diodes to be identified prior to stack assembly, thus minimizing the risk of completing an assembly only to find that it does not meet specifications due to one or more defective laser diodes. Thus the present stack assembly improves on assembly fabrication efficiency, both in terms of time and materials. Second, early testing allows improved matching of the performance of the individual laser diodes within an assembly, for example providing a means of achieving improved wavelength matching between laser diodes or allowing laser diodes operating at different wavelengths to be grouped together in the desired order.

During the next series of steps the laser diode stack, which is comprised of a stack of laser diode subassemblies 1100, is fabricated. The perspective view of FIG. 12 shows a stack 1200 comprised of six subassemblies 1100 along with an additional submount 1201. Although laser diode stack 1200 can be fabricated without additional submount 1201, the inventors have found that it improves the mechanical reliability of the laser diode package. It will be appreciated that the laser diode stack can utilize fewer, or greater, numbers of subassemblies 1100 and that either horizontal or vertical stack assemblies can be fabricated.

In a preferred embodiment of the invention, laser diodes 1109 are serially coupled together. In this embodiment the individual submount assemblies 1100 are combined into a single assembly by bonding the upper surface of each contact pad 1105 to a portion of the lower surface of the adjacent submount 1101, submounts 1101 being comprised of an electrically conductive material. Preferably solder 1203 coupling contact pads 1105 to submounts 1101 has a lower melting temperature than the solder used to fabricate subassembly 1101, thus insuring that during this stage of assembly the reflow process used to combine the subassemblies will not damage the individual assemblies. In a preferred embodiment of the invention, a silver-tin solder is used with a melting temperature lower than that of the Au—Sn solder preferably used for solder joint 1103.

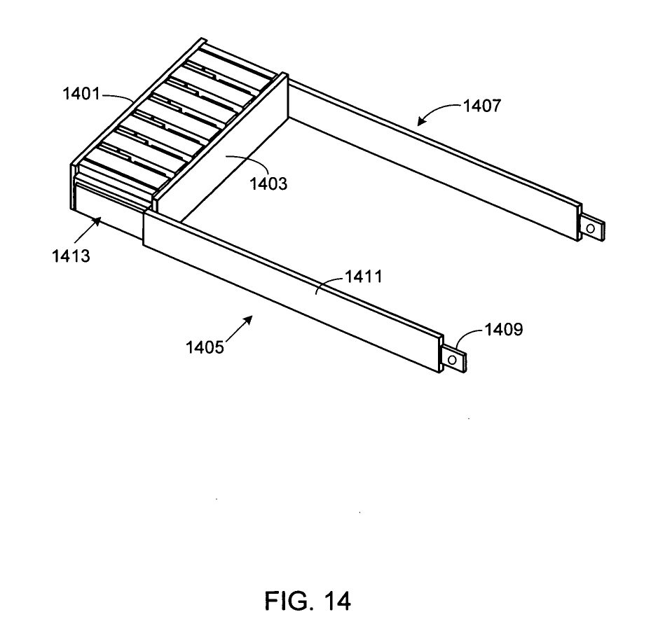

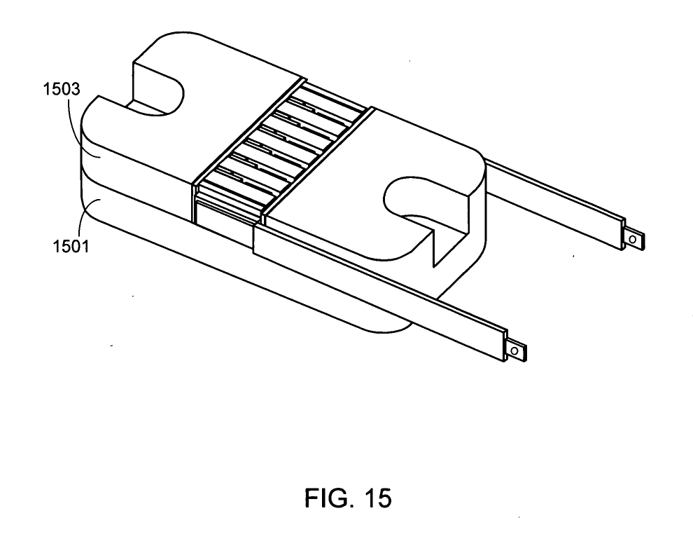

In the next series of processing steps, illustrated in FIGS. 13 and 14, an electrically isolating backplane member 1301 as well as electrically isolating side frame members 1401 and 1403 are attached to the back surface and the side surfaces, respectively, of submounts 1101. In the preferred embodiment members 1301, 1401 and 1403 are fabricated from beryllium oxide, a material that is both thermally conductive and electrically isolating. It will be appreciated that other thermally conductive/electrically isolating materials, such as aluminum nitride, CVD diamond or silicon carbide, can be used for members 1301, 1401 and 1403. Preferably the solder used to attach members 1301, 1401 and 1403 to submounts 1301 has a lower melting temperature than that used to couple together subassemblies 1100 (i.e., solder 1203). Accordingly in at least one embodiment a tin-indium-silver solder is used.

In an alternate embodiment of the invention laser diodes 1109 are not serially coupled together, rather they are coupled together in parallel, or they are individually addressable. Individual addressability allows a subset of the total number of laser diodes within the stack to be activated at any given time. In order to achieve individual addressability, or to couple the laser diodes together in a parallel fashion, the electrically conductive path between individual subassemblies must be severed, for example using a pad 1105 that is not electrically conductive, and/or using a submount 1101 that is not electrically conductive, and/or placing an electrically isolating layer between submounts 1101 and pads 1105 within assembly 1200. Parallel connections as well as individual laser diode connections can be made, for example, by coupling interconnect cables to metallization layers 1103 and 1111. Additionally one or more of members 1301, 1401 and 1403 can be patterned with electrical conductors, thus providing convenient surfaces for the inclusion of circuit boards that can simplify the relatively complex wiring needed to provide individual laser diode addressability.

In the preferred package assembly process and assuming that the laser diode subassemblies are serially coupled together, the same mounting fixture that is used to attach side members 1401 and 1403 to submounts 1101 is also used to attach contact assemblies 1405 and 1407 to the laser diode package. Preferably contact assemblies 1405 and 1407 are assembled in advance using a higher melting temperature solder such as a gold-tin solder. Each contact assembly 1405/1407 includes a wire 1409, covered with an insulator 1411 (e.g., Kapton), and a contact (or contact assembly) 1413.

In the preferred embodiment, the laser diode assembly, shown in FIGS. 13 and 14, is attached to a cooler body as illustrated in FIG. 15. Preferably the cooler body is comprised of two parts; a primary member 1501 and a secondary member 1503. The benefit of having two members 1501/1503 rather than a single slotted member is that it is easier to achieve a closer fit between the cooler body and the laser diode submount stack assembly, thus insuring more efficient heat transfer and thus assembly cooling. Preferably bottom member 1301 and side members 1401 and 1403 are soldered to members 1501/1503 of the cooler body, thus insuring a mechanically robust assembly.

As will be understood by those familiar with the art, the present invention may be embodied in other specific forms without departing from the spirit or essential characteristics thereof. Accordingly, the disclosures and descriptions herein are intended to be illustrative, but not limiting, of the scope of the invention which is set forth in the following claims.

What is claimed is:

1. An end-pumped solid state laser comprising:
at least two laser diode subassemblies, wherein each of said at least two laser diode subassemblies comprises:
a submount, said submount further comprising a first mounting surface and a second mounting surface;
at least one laser diode attached to a first portion of said first mounting surface of said submount, wherein a fast axis corresponding to an output beam of said at least one laser diode is substantially perpendicular to said first surface of said submount, and wherein said at least one laser diode is not a laser diode bar; and
a spacer attached to a second portion of said first mounting surface of said submount;
means for mechanically coupling each laser diode subassembly spacer to said second mounting surface of said submount of an adjacent laser diode subassembly to form a laser diode stack;
a laser gain medium mounted adjacent to said laser diode stack; and
means for optically coupling said output beams from each of said at least one laser diode of each of said at least two laser diode subassemblies into an end surface of said laser gain medium.

2. The end-pumped solid state laser of claim 1, wherein said laser gain medium is cylindrically shaped.

3. The end-pumped solid state laser of claim 1, further comprising a first reflective element and a second reflective element, wherein said first and second reflective elements form a laser cavity, wherein said laser gain medium is contained within said laser cavity.

4. The end-pumped solid state laser of claim 1, wherein said optical coupling means further comprises at least one lens interposed between said laser gain medium and said laser diode stack.

5. The end-pumped solid state laser of claim 1, further comprising a cooling block in thermal communication with each submount of said at least two laser diode subassemblies.

6. The end-pumped solid state laser of claim 5, further comprising a backplane member interposed between a back surface of each submount of said at least two laser diode subassemblies and said cooling block.

7. The end-pumped solid state laser of claim 6, wherein said backplane member is comprised of an electrically isolating material.

8. The end-pumped solid state laser of claim 7, wherein said electrically isolating material is selected from the group consisting of aluminum nitride, beryllium oxide, CVD diamond and silicon carbide.

9. The end-pumped solid state laser of claim 5, further comprising a side frame member interposed between a side surface of each submount of said at least two laser diode subassemblies and said cooling block.

10. The end-pumped solid state laser of claim 9, wherein said side frame member is comprised of an electrically isolating material.

11. The end-pumped solid state laser of claim 10, wherein said electrically isolating material is selected from the group consisting of aluminum nitride, beryllium oxide, CVD diamond and silicon carbide.

12. The end-pumped solid state laser of claim 5, further comprising:
a backplane member interposed between a back surface of each submount of said at least two laser diode subassemblies and said cooling block;
a first side frame member interposed between a first side surface of each submount of said at least two laser diode subassemblies and said cooling block; and
a second side frame member interposed between a second side surface of each submount of said at least two laser diode subassemblies and said cooling block.

13. The end-pumped solid state laser of claim 5, wherein said cooling block is comprised of a first member and a second member, wherein said first and second cooling block members form a slotted region, and wherein said at least two laser diode subassemblies fit within said slotted region.

14. The end-pumped solid state laser of claim 1, wherein each submount of said at least two laser diode subassemblies is comprised of an electrically conductive material.

15. The end-pumped solid state laser of claim 14, wherein said electrically conductive material is selected from the group consisting of copper, copper tungsten, copper molybdenum, matrix metal composites and carbon composites.

16. The end-pumped solid state laser of claim 1, further comprising a solder layer interposed between each of said at least one laser diode and said first portion of said first mounting surface of each submount of said at least two laser diode subassemblies.

17. The end-pumped solid state laser of claim 1, said spacer further comprising an electrical isolator attached to said second portion of said first mounting surface of said submount and an electrical contact pad attached to said electrical isolator.

18. The end-pumped solid state laser of claim 17, further comprising a metallization layer deposited on a top surface of said electrical isolator of each of said at least two laser diode subassemblies, wherein said electrical contact pad is in electrical communication with said metallization layer.

19. The end-pumped solid state laser of claim 18, further comprising at least one wire bond coupling said at least one laser diode and said metallization layer of each of said at least two laser diode subassemblies.

20. The end-pumped solid state laser of claim 18, further comprising at least one ribbon bond coupling said at least one laser diode and said metallization layer of each of said at least two laser diode subassemblies.

21. The end-pumped solid state laser of claim 17, wherein said mechanically coupling means further comprises means for electrically connecting each electrical contact pad to said second surface of said submount of said adjacent laser diode subassembly.

22. The end-pumped solid state laser of claim 21, wherein said electrically connecting means is comprised of a solder layer.

23. The end-pumped solid state laser of claim 1, wherein the fast axis of each laser diode is co-aligned with the fast axis of a corresponding laser diode on said adjacent laser diode subassembly.

24. The end-pumped solid state laser of claim 1, wherein said at least one laser diode of said at least two laser diode subassemblies is a single mode single emitter laser diode.

25. The end-pumped solid state laser of claim 1, wherein said at least one laser diode of said at least two laser diode subassemblies is a broad area multi-mode single emitter laser diode.

26. The end-pumped solid state laser of claim 1, wherein said at least one laser diode of said at least two laser diode subassemblies is comprised of multiple single emitters on multiple substrates.

27. The end-pumped solid state laser of claim 1, wherein said at least one laser diode of said at least two laser diode subassemblies is comprised of multiple single emitters on a single substrate.

28. The end-pumped solid state laser of claim 1, wherein each of said at least one laser diodes of each of said at least two laser diode subassemblies is individually addressable.

29. The end-pumped solid state laser of claim 1, wherein said output beams from each of said at least one laser diode of each of said at least two laser diode subassemblies include at least a first wavelength and a second wavelength.

30. The end-pumped solid state laser of claim 29, wherein a first plurality of said laser diode subassemblies produce said first wavelength and a second plurality of said laser diode subassemblies produce said second wavelength.

31. The end-pumped solid state laser of claim 30, wherein said first and second pluralities of said laser diode subassemblies alternate in position within said laser diode stack.

32. The end-pumped solid state laser of claim 29, wherein each laser diode attached to each submount of each of said at least two laser diode subassemblies is comprised of multiple single emitters, wherein a first plurality of said multiple single emitters produce said first wavelength and a second plurality of said multiple single emitters produce said second wavelength.

33. The end-pumped solid state laser of claim 32, wherein said first and second pluralities of multiple single emitters are fabricated on individual substrates.

34. The end-pumped solid state laser of claim 1, wherein said optical coupling means includes at least one fast axis reducing lens.

35. The end-pumped solid state laser of claim 1, wherein said optical coupling means includes at least one fast axis reducing lens for each of said at least one laser diodes.
